(19) United States
(12) Patent Application Publication
(10) Pub. No.: US 2025/0120296 A1
(43) Pub. Date: Apr. 10, 2025

(54) LASER IRRADIATION DEVICE AND METHOD FOR MANUFACTURING DISPLAY DEVICE USING THE SAME

(71) Applicants: Samsung Display Co., LTD., Yongin-si (KR); WI-A CORPORATION, Hwaseong-si (KR)

(72) Inventors: JEONGJIN PARK, Yongin-si (KR); YONG MUN KIM, Hwaseong-si (KR); BYUNGHOON KIM, Yongin-si (KR); YOUN HYUN NAM, Hwaseong-si (KR); BYEONG GYU PARK, Hwaseong-si (KR)

(21) Appl. No.: 18/819,944

(22) Filed: Aug. 29, 2024

(30) Foreign Application Priority Data
Oct. 5, 2023 (KR) 10-2023-0132707

(51) Int. Cl. H10K 71/00; B23K 26/066; H10K 59/12; H10K 59/131

(52) U.S. Cl. CPC H10K 71/621; B23K 26/066; H10K 59/1201; H10K 59/131

(57) ABSTRACT

A laser irradiation device includes an optical system including a light source emitting a laser, a pattern mask including a plurality of patterns on which the laser emitted from the optical system is incident and through which the laser passes, and a moving module moving the pattern mask in a direction perpendicular to the substrate while irradiating the metal layer with the laser to control an area in which the metal layer is irradiated with the laser. The plurality of pad electrodes and the plurality of bump electrodes are electrically connected through the plurality of metal patterns.

This application claims priority to Korean Patent Application No. 10-2023-0132707, filed on Oct. 5, 2023, and all the benefits accruing therefrom under 35 U.S.C. § 119, the content of which in its entirety is herein incorporated by reference.

### BACKGROUND

### 1. Field

The disclosure herein relates to a laser irradiation device and a method for manufacturing a display device using the same, and more particularly, to a laser irradiation device having improved reliability and a method for manufacturing a display device using the same.

### 2. Description of the Related Art

Electronic devices such as smartphones, tablets, laptop computers, car navigation systems, and smart televisions are being developed. These electronic devices are provided with display devices for providing information.

Various types of display devices are being developed to satisfy the user experience/user interface (“UX/UI”) of users. Display devices for providing a wide display region and a relatively small non-display region are being developed.

In general, a laser device may be used in the process of manufacturing electrical and electronic devices such as display devices. Specifically, the laser device may be used for drilling, cutting, cleaning, marking, scanning, crystallizing, and surface-modifying workpieces. To this end, a technology that may easily regulate the shape, size, and energy density of laser beams generated from the laser device is desired.

### SUMMARY

The disclosure provides a laser irradiation device configured to reduce damage to a substrate during a process of patterning, and a method for manufacturing a display device using the same.

An embodiment of the inventive concept provides a laser irradiation device irradiating a metal layer overlapping a plurality of pad electrodes disposed on a substrate and a plurality of bump electrodes each disposed to correspond to the plurality of pad electrodes and having a non-uniform thickness with a laser to form a plurality of metal patterns spaced apart in a first direction. The laser irradiation device includes an optical system including a light source emitting the laser, a pattern mask including a plurality of patterns on which the laser emitted from the optical system is incident and through which the laser passes, and a moving module moving the pattern mask in a direction perpendicular to the substrate while irradiating the metal layer with the laser to control an area in which the metal layer is irradiated with the laser. The plurality of pad electrodes and the plurality of bump electrodes are electrically connected through the plurality of metal patterns.

In an embodiment, the plurality of patterns may be arranged in the first direction and may not overlap the plurality of metal patterns.

In an embodiment, the plurality of patterns may be formed to incline at a predetermined angle in a plan view with respect to the plurality of pad electrodes.

In an embodiment, the plurality of patterns may include first sub-patterns and second sub-patterns, which are spaced apart in a second direction crossing the first direction.

In an embodiment, the first sub-patterns and the second sub-patterns may be alternately disposed in the first direction in a plan view.

In an embodiment, a plurality of open areas may be defined between two adjacent metal patterns among the plurality of metal patterns.

In an embodiment, the plurality of patterns may overlap the plurality of open areas in a plan view.

In an embodiment, the pattern mask may be disposed between the optical system and the substrate.

In an embodiment, the pattern mask may be disposed parallel to the substrate.

In an embodiment, the laser emitted from the light source may have a wavelength of about 200 nanometers (nm) to about 400 nm.

In an embodiment, the laser emitted from the optical system may include a laser line beam.

In an embodiment, the laser irradiation device may further include an optical lens between the substrate and the pattern mask.

In an embodiment, the optical lens may include a chromatic aberration lens.

In an embodiment of the inventive concept, a method for manufacturing a display device includes providing a plurality of pad electrodes disposed on a base layer and arranged in a first direction, and a plurality of bump electrodes disposed on the plurality of pad electrodes and overlapping each of the plurality of pad electrodes in a plan view, disposing a metal layer having a non-uniform thickness on the plurality of pad electrodes and the plurality of bump electrodes, irradiating the metal layer with a laser, using a laser irradiation device including a pattern mask including a plurality of patterns, and forming a plurality of metal patterns overlapping the plurality of pad electrodes and the plurality of bump electrodes and spaced apart in the first direction. The plurality of pad electrodes and the plurality of bump electrodes are electrically connected through the plurality of metal patterns.

In an embodiment, the irradiating the metal layer with the laser may include patterning the metal layer, in the plan view, overlapping an area between two adjacent pad electrodes among the plurality of pad electrodes.

In an embodiment, the patterning of the metal layer may include irradiating the metal layer, in the plan view, overlapping an area between the two adjacent pad electrodes among the plurality of pad electrodes with the patterned laser subjected to passing through the pattern mask.

In an embodiment, the patterning of the metal layer may include moving the pattern mask in a direction away from the base layer through a moving module.

In an embodiment, while the pattern mask moves, an irradiation area of the laser patterned by passing through the pattern mask may gradually increase, and a thickness of the metal layer may gradually decrease.

In an embodiment, a plurality of open areas may be defined between two adjacent metal patterns among the plurality of metal patterns, and the plurality of open areas may overlap the plurality of patterns in the plan view.

In an embodiment, the method may further include planarizing the metal layer, using the laser irradiation device including a planarization mask before the forming of the plurality of metal patterns.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept.

In the drawings:

FIG. 1 is a perspective view of an embodiment of an electronic device according to the inventive concept;

FIG. 2 is an exploded perspective view of an embodiment of an electronic device according to the inventive concept;

FIG. 3 is a cross-sectional view of a display device, taken along line I-I′ of FIG. 2;

FIG. 4 is a brief cross-sectional view of an embodiment of a display module according to the inventive concept;

FIG. 5 is a plan view of an embodiment of a display panel according to the inventive concept;

FIG. 6 is a cross-sectional view of an embodiment of a display module according to the inventive concept;

FIG. 7A is a view enlarging a portion of an embodiment of a display device according to the inventive concept;

FIG. 7B is a cross-sectional view of a base layer, taken along line II-II′ of FIG. 7A;

FIG. 8 is a perspective view of an embodiment of a laser irradiation device according to the inventive concept;

FIG. 9 is a cross-sectional view showing components of an optical system shown in FIG. 8;

FIG. 10A is a plan view of a pattern mask shown in FIG. 8;

FIGS. 10B and 10C are plan views showing another embodiment of the pattern mask shown in FIG. 8;

FIGS. 11A to 11C are views showing an irradiation target shown in FIG. 8;

FIG. 12A is a perspective view of an embodiment of a laser irradiation device according to the inventive concept;

FIG. 12B is a plan view of an open mask shown in FIG. 12A;

FIG. 12C is a cross-sectional view taken along line V-V′ of FIG. 12A; and

FIGS. 13A to 15B are views showing an embodiment of a process of forming a metal pattern using a laser irradiation device according to the inventive concept.

### DETAILED DESCRIPTION

The disclosure may be modified in many alternate forms, and thus illustrative embodiments will be exemplified in the drawings and described in detail. It should be understood, however, that it is not intended to limit the disclosure to the particular forms disclosed, but rather, is intended to cover all modifications, equivalents, and alternatives falling within the spirit and scope of the disclosure.

It will be understood that when an element (or a region, a layer, a portion, or the like) is referred to as “being on”, “connected to” or “coupled to” another element, it may be directly disposed on, connected or coupled to the other element, or intervening elements may be disposed therebetween.

Like reference numerals refer to like elements. In addition, in the drawings, the thickness, the ratio, and the dimensions of elements are exaggerated for an effective description of technical contents.

The term “and/or,” includes all combinations of one or more of which associated configurations may define.

Although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

In addition, terms such as “below,” “lower,” “above,” “upper,” and the like are used to describe the relationship of the configurations shown in the drawings. The terms are used as a relative concept and are described with reference to the direction indicated in the drawings.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “includes” or “including”, when used in this specification, specify the presence of stated features, integers, steps, operations, elements, components, or a combination thereof, but do not preclude the presence or addition of one or more other features, integers, steps, operations, elements, components, or combinations thereof.

Hereinafter, embodiments of the inventive concept will be described with reference to the drawings.

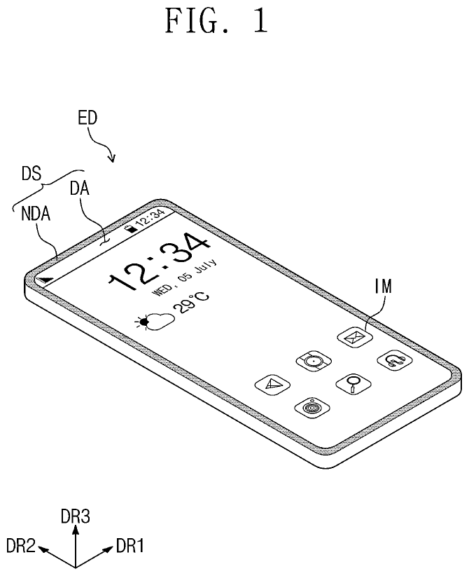

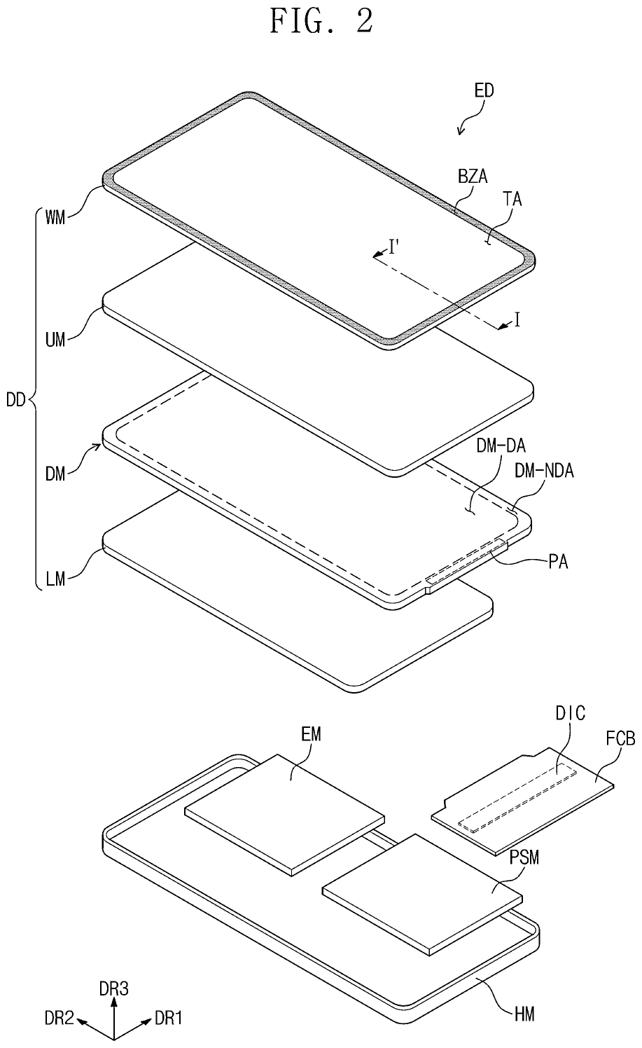

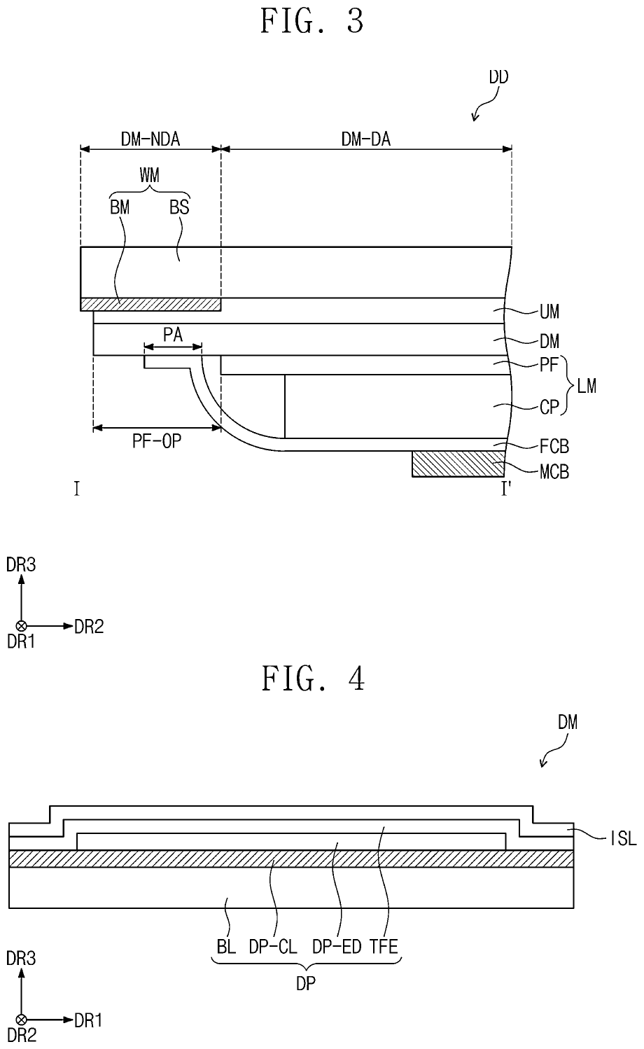

FIG. 1 is a perspective view of an embodiment of an electronic device according to the inventive concept. FIG. 2 is an exploded perspective view of an embodiment of an electronic device according to the inventive concept. FIG. 3 is a cross-sectional view of a display device, taken along line I-I′ of FIG. 2.

Referring to FIG. 1, an electronic device ED in an embodiment of the inventive concept may include a display surface DS defined by a first direction DR1 and a second direction DR2 crossing the first direction DR1. The electronic device ED may provide an image IM to users through the display surface DS.

The display surface DS may include a display region DA and a non-display region NDA around the display region DA. The display region DA may be a region displaying the image IM, and the non-display region NDA may be a region that does not display the image IM. The non-display region NDA may surround the display region DA. However, the inventive concept is not limited thereto, and the shape of the display region DA and the shape of the non-display region NDA may be modified.

Hereinafter, a direction substantially perpendicularly crossing a plane defined by the first direction DR1 and the second direction DR2 is defined as a third direction DR3. Front and rear surfaces of each member are distinguished from each other with respect to the third direction DR3. In addition, as used herein, “in a plan view” may be defined as a state in which the display device DD is viewed from the third direction DR3.

In an embodiment of the inventive concept, the electronic device ED may be a foldable electronic device which is foldable around a folding axis. The folding axis may be parallel to the first direction DR1 or the second direction DR2, and a folding region may be defined in a portion of the display region DA. The electronic device ED may be in-folded such that portions of the display region DA face each other, or may be out-folded such that portions of the display region DA are folded away from each other.

As shown in FIG. 2, the electronic device ED may include a display device DD, an electronic module EM, a power module PSM, and a housing HM. FIG. 2 briefly shows the electronic device ED, and the electronic device ED may further include a mechanical structure (e.g., a hinge) designed to control an operation (e.g., folding or rolling) of the display device DD.

The display device DD generates the image IM and detects external inputs. The display device DD includes a window WM, an upper member UM, a display module DM, a lower member LM, a flexible circuit board FCB, and a driving chip DIC. The upper member UM includes members disposed above the display module DM, and the lower member LM includes members disposed below the display module DM.

The window WM provides a front surface of the electronic device ED. The window WM includes a transmission region TA and a bezel region BZA. The display region DA and the non-display region NDA of the display surface DS shown in FIG. 1 are defined by the transmission region TA and the bezel region BZA. The transmission region TA is a region through which images pass, and the bezel region BZA is a region covering structures/members disposed below the window WM.

The display module DM includes a display region DM-DA and a non-display region DM-NDA corresponding to the display region DA and the non-display region NDA shown in FIG. 1. As used herein, the phrase “a region/portion corresponds to a region/portion” indicates that they overlap and are not limited to the same area.

A pad region PA is disposed on one side of the non-display region DM-NDA. The pad region PA is a region electrically bonded (or connected) to a flexible circuit board FCB, which will be described later. In the illustrated embodiment, the pad region PA is defined on a rear surface of the display module DM.

The display module DM has a substantially quadrangular shape. The “substantially quadrangular shape” herein includes a quadrangular shape defined mathematically as well as a shape similar to a quadrangle that may be seen as a quadrangular by users. In an embodiment, the substantially quadrangular shape may include a quadrangle shape having rounded corner regions, for example. In addition, the substantially quadrangular shape is not necessarily limited to a straight edge of a display panel DP, and the edge may include a curved region.

The upper member UM may include a protection film or an optical film. The optical film may include a polarizer and a retarder to reduce reflection of external light. The lower member LM may include a protection film protecting the display panel DP, a support member supporting the display panel DP, and a digitizer. Detailed descriptions of the upper member UM and the lower member LM will be described later.

The flexible circuit board FCB is disposed below the display module DM. The flexible circuit board FCB may be bonded to a rear surface of the display panel DP. The flexible circuit board FCB electrically connects the display panel DP and a main circuit board MCB (refer to FIG. 3). The flexible circuit board FCB includes at least one insulating layer and at least one conductive layer. The conductive layer may include a plurality of signal lines.

The driving chip DIC may be disposed (e.g., mounted) on the flexible circuit board FCB. The driving chip DIC may include driving circuits, e.g., a data driving circuit, for driving pixels of the display panel DP. FIG. 2 shows a structure in which the driving chip DIC is disposed (e.g., mounted) on the flexible circuit board FCB, but the inventive concept is not limited thereto. In an embodiment, the driving chip DIC may be disposed (e.g., mounted) on the display module DM or on a main circuit board, for example.

The electronic module EM may include a control module, a wireless communication module, an image input module, an audio input module, an audio output module, a memory, and an external interface module. The electronic module EM may include a main circuit board, and the modules may be disposed (e.g., mounted) on the main circuit board or may electrically be connected to the main circuit board through a flexible circuit board. The electronic module EM is electrically connected to a power module PSM.

Although not shown separately, the electronic device ED may further include an electro-optical module. The electro-optical module may be an electronic component that outputs or receives optical signals. The electro-optical module may include a camera module and/or a proximity sensor. The camera module may capture external images through a partial region of the display panel DP.

The housing HM shown in FIG. 2 is bonded to the display device DD, particularly the window WM, to accommodate the other modules. The housing HM is shown to have a single body shape, but is not limited thereto. The housing HM may include a plurality of portions (e.g., a side edge portion and a bottom portion) bonded to each other.

Referring to FIG. 3, the window WM may include a base substrate BS and a bezel pattern BM disposed on a lower surface of the base substrate BS. The base substrate BS may include a synthetic resin film or a glass substrate. The base substrate BS may have a multilayer structure. The base substrate BS may include a thin film glass substrate, a protection film disposed on the thin film glass substrate, and an adhesive layer bonding the thin film glass substrate and the protection film.

The bezel pattern BM is a colored light-shielding film and may be formed, e.g., through a coating method. The bezel pattern BM may include a base material and a dye or a pigment mixed with the base material. The bezel pattern BM overlaps the non-display region NDA shown in FIG. 1 and the bezel region BZA shown in FIG. 2. The bezel pattern BM may be disposed on the lower surface of the base substrate BS. When the base substrate BS has a multilayer structure, the bezel pattern BM may be disposed between interfaces defined by a plurality of layers. In an embodiment, the bezel pattern BM may be disposed between the thin film glass substrate and the protection film, for example. Although not shown separately, the window WM may further include at least one of a hard coating layer, an anti-fingerprint layer, or an anti-reflection layer on an upper surface of the base substrate BS

The upper member UM may include an upper film. The upper film may include a synthetic resin film. The synthetic resin film may include polyimide, polycarbonate, polyamide, triacetylcellulose, polymethylmethacrylate, or polyethylene terephthalate.

The upper film may absorb external shocks applied to a front surface of the display device DD. In an embodiment of the inventive concept, the display module DM may include a color filter that replaces a polarizing film as an anti-reflection member, and accordingly, the display device DD may have reduced front impact strength. As the color filter is applied, the upper film may compensate for the reduced impact strength.

The upper member UM overlaps the bezel region BZA (refer to FIG. 2) and the transmission region TA (refer to FIG. 2). The upper member UM may overlap only a portion of the bezel region BZA. A portion of the bezel pattern BM may be exposed from the upper member UM. In an embodiment of the inventive concept, the upper member UM may not be provided. In an embodiment of the inventive concept, the upper member UM may be replaced with an optical film including a polarizer and a retarder.

Although not shown, an adhesive layer bonding the upper member UM and the window WM may be further included between the upper member UM and the window WM. The adhesive layer may be a pressure sensitive adhesive film (“PSA”) or an optically clear adhesive (“OCA”).

The display module DM is disposed below the upper member UM. The display module DM overlaps the bezel region BZA and the transmission region TA. The display module DM may cover an entirety of the upper member UM in the bezel region BZA. A side surface of the display module DM may be aligned with a side surface of the upper member UM, and a corner of the display module DM may be aligned with a corner of the upper member UM in a plan view.

The pad region PA of the display module DM may overlap the upper member UM in the bezel region BZA. A portion of the display module DM corresponding to the pad region PA may be bonded to a lower surface of the upper member UM through an adhesive layer. The pad region PA overlaps the upper member UM, and a portion of the display module DM overlapping the pad region PA is bonded to the upper member UM, and accordingly, the upper member UM may sufficiently support the pad region PA when the flexible circuit board FCB is bonded to the pad region PA.

The lower member LM may include a lower film PF and a cover panel CP. In an embodiment of the inventive concept, the lower member LM may further include a support plate and a digitizer.

The lower film PF may expose the pad region PA of the display module DM. The lower film PF may have a smaller size of area than the display module DM. In an embodiment, the lower film PF may only overlap the display region DM-DA of the display module DM, for example. An open region PF-OP corresponding to the non-display region DM-NDA may be defined in the lower film PF. In an alternative embodiment, the lower film PF may have a size that substantially corresponds to the display module DM. In this case, the open region PF-OP corresponding to the pad region PA may be defined in the lower film PF. The pad region PA may be exposed through the open region PF-OP.

The lower film PF may expose the pad region PA. The lower film PF may have a smaller area than the display module DM. In an embodiment, the lower film PF may overlap only the display region DA, for example. The lower film PF may have substantially the same area as the display module DM. The open region PF-OP corresponding to the pad region PA may be defined in the lower film PF. The pad region PA may be exposed through the open region PF-OP.

The cover panel CP may be disposed below the lower film PF. The cover panel CP may increase resistance against compressive force caused by external pressing. Accordingly, the cover panel CP may serve to prevent deformation of the display module DM. The cover panel CP may include a flexible plastic material such as polyimide or polyethylene terephthalate. In addition, the cover panel CP may be a colored film having relatively low light transmittance. The cover panel CP may absorb light incident from the outside. In an embodiment, the cover panel CP may be a black synthetic resin film, for example. When the display device DD is viewed from an upper side of the window WM, components disposed below the cover panel CP may not be viewed by users.

Although not shown, a support plate may be further disposed below the cover panel CP. The support plate may include a metal material having relatively high strength. The support plate may include reinforcing fiber composite materials. The support plate may include reinforcing fibers disposed inside a matrix portion. The reinforcing fibers may be carbon fibers or glass fibers. The matrix portion may include a polymer resin. The matrix portion may include a thermoplastic resin. In an embodiment, the matrix portion may include a polyamide-based resin or a polypropylene-based resin, for example. In an embodiment, the reinforcing fiber composite material may be carbon fiber reinforced plastic (“CFRP”) or glass fiber reinforced plastic (“GFRP”), for example.

The main circuit board MCB may be disposed on a lower surface of the flexible circuit board FCB. The flexible circuit board FCB may include an insulating film and conductive lines disposed (e.g., mounted) on the insulating film. The main circuit board MCB may include signal lines and electronic elements which are not shown in the drawing. The electronic elements may be connected to the signal lines and thus may be electrically connected to the display module DM. The electronic elements generate various electrical signals, e.g., a signal for producing images or a signal for sensing an external input, or perform processing on the sensed signals. A single main circuit board MCB or three or more main circuit board MCB may be provided corresponding to each electrical signal for generation and processing, but is not limited to a particular embodiment.

Although not shown, the main circuit board MCB may include a driving chip DIC (refer to FIG. 2) disposed (e.g., mounted) in the main circuit board MCB.

Referring to FIGS. 2 and 3, a flexible circuit board FCB is bonded to a rear surface of the display panel DP (rear surface bonding). The non-display region DM-NDA of the display panel DP is not bent, and accordingly, defects that are caused when the non-display region DM-NDA of the display panel DP is bent may be prevented. In addition, an area of the bezel region BZA of the window WM to cover the non-display region DM-NDA of the display panel DP may be reduced.

FIG. 4 is a brief cross-sectional view of an embodiment of a display module according to the inventive concept.

Referring to FIG. 4, the display module DM may include a display panel DP and an input sensing layer ISL. The display panel DP may include a base layer BL, a circuit layer DP-CL, a display element layer DP-ED, and an encapsulation layer TFE.

The circuit layer DP-CL is disposed on an upper surface of the base layer BL. The base layer BL may be a flexible substrate that is bendable, foldable, rollable, or the like. The base layer BL may be a glass substrate, a metal substrate, or a polymer substrate. However, the inventive concept is not limited thereto, and the base layer BL may be an inorganic layer, an organic layer, or a composite material layer. The base layer BL has substantially the same shape as that of the display panel DP.

The base layer BL may have a multi-layered structure. In an embodiment, the base layer BL may include a first synthetic resin layer, a second synthetic resin layer, and inorganic layers disposed therebetween, for example. The first and second synthetic resin layers each may include a polyimide-based resin, and is not particularly limited.

The circuit layer DP-CL may be disposed on the base layer BL. The circuit layer DP-CL may include a plurality of insulating layers, a plurality of semiconductor patterns, a plurality of conductive patterns, signal lines, or the like. The circuit layer DP-CL may include a driving circuit of pixels. Hereinafter, unless otherwise specified, when components A and B are disposed in the same layer, they are interpreted to be formed through the same process and to have the same materials or the same stack structure as each other. Conductive patterns or semiconductor patterns disposed in the same layer may be interpreted as described above.

The display element layer DP-ED may be disposed on the circuit layer DP-CL. The display element layer DP-ED may include a light-emitting element. In an embodiment, the light-emitting element may include organic light-emitting materials, inorganic light-emitting materials, organic-inorganic light-emitting materials, quantum dots, quantum rods, micro light-emitting diodes (“LEDs”), or nano LEDs, for example.

The encapsulation layer TFE may be disposed on the display element layer DP-ED. The encapsulation layer TFE may serve to protect the light-emitting element layer DP-ED, that is a light-emitting element, from moisture, oxygen, and foreign substances such as dust particles. The encapsulation layer TFE may include at least one inorganic encapsulation layer. The encapsulation layer TFE may include a stack structure of a first inorganic encapsulation layer/an organic encapsulation layer/a second inorganic encapsulation layer.

The input sensing layer ISL may be directly disposed on the display panel DP. The input sensing layer ISL may detect user inputs using, e.g., an electromagnetic induction method or a capacitive method. The display panel DP and the input sensing layer ISL may be formed through a roll-to-roll process. The term such as “being directly disposed” as described herein may indicate that a third component is not disposed between the input sensing layer ISL and the display panel DP. In an embodiment, a separate adhesive layer may not be disposed between the input sensing layer ISL and the display panel DP, for example.

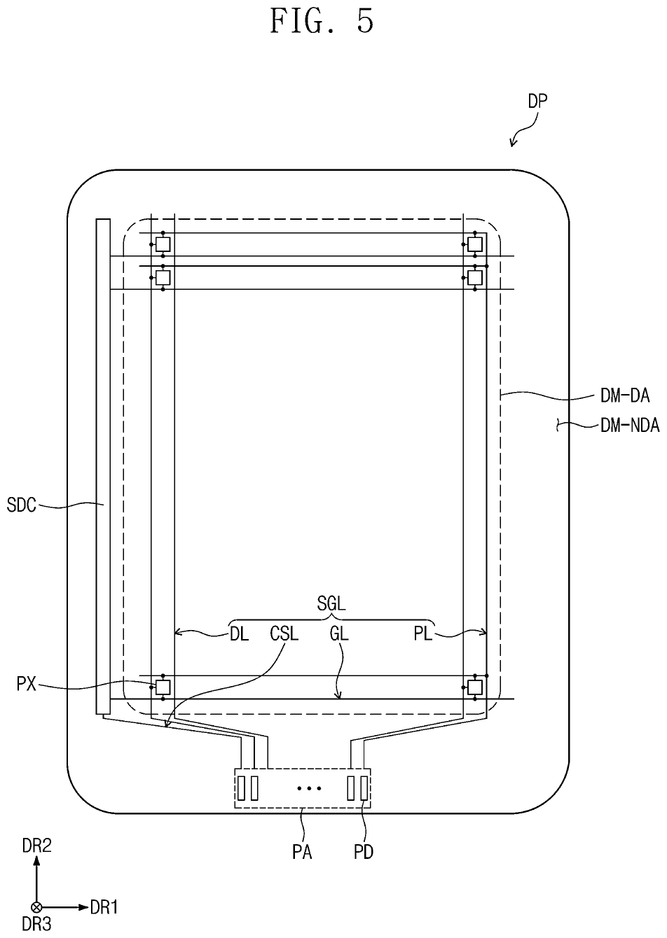

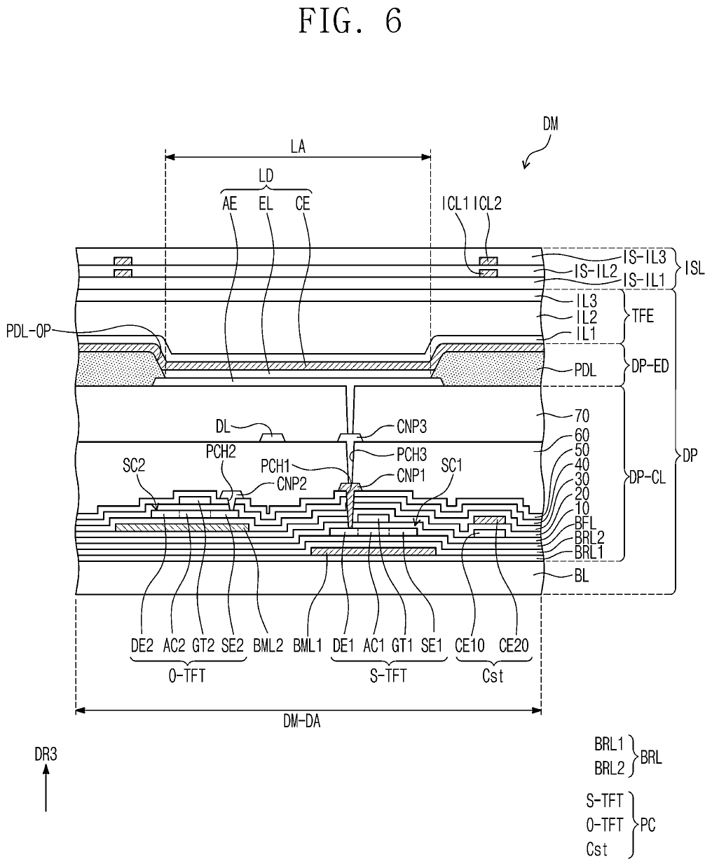

FIG. 5 is a plan view of an embodiment of a display panel according to the inventive concept. FIG. 6 is a cross-sectional view of an embodiment of a display module according to the inventive concept. Specifically, FIG. 5 is a plan view of the display panel DP viewed from the third direction DR3.

As shown in FIG. 5, the display panel DP may include a scan driving circuit SDC, a plurality of signal lines SGL, and a plurality of pixels PX. The plurality of pixels PX are disposed in the display region DM-DA. Each of the pixels PX includes a light-emitting element and a pixel driving circuit connected thereto. The scan driving circuit SDC, the plurality of signal lines SGL, and the pixel driving circuit may be included in the circuit layer DP-CL shown in FIG. 4.

The scan driving circuit SDC may include a gate driving circuit. The gate driving circuit generates a plurality of scan signals and sequentially outputs the plurality of scan signals to a plurality of scan lines GL respectively, which will be described later. The scan driving circuit SDC may further include a light-emitting driving circuit that is distinct from the gate driving circuit. The light-emitting driving circuit may output scan signals to another group of scan lines.

The scan driving circuit SDC may include a plurality of thin film transistors formed through the same process as the pixel driving circuit, e.g., a low temperature polycrystaline silicon (“LTPS”) process or a low temperature polycrystalline oxide (“LTPO”) process.

The plurality of signal lines SGL include scan lines GL, data lines DL, a power line PL, and a control signal line CSL. Each of the scan lines GL is connected to a corresponding pixel PX among the plurality of pixels PX, and each of the data lines DL is connected to a corresponding pixel PX among the plurality of pixels PX. The power line PL is connected to the plurality of pixels PX. The data lines DL provide data signals to the pixels PX. The control signal line CSL may provide control signals to the scan driving circuit SDC.

A plurality of power lines PL may be provided. In an embodiment, the power lines PL may include a first power line receiving a first power voltage and a second power line receiving a second power voltage at a higher level than the first power voltage, for example. The first power voltage is provided to the pixels PX through the first power line, and the second power voltage is provided to the pixels PX through the second power line. FIG. 5 shows one control signal line CSL in an embodiment, but a plurality of control signal lines CSL may be provided.

The scan lines GL, the data lines DL, and the power line PL may overlap the display region DM-DA and the non-display region DM-NDA, and the control signal line CSL may overlap the non-display region DM-NDA. Ends of the plurality of signal lines SGL may be aligned at one side of the non-display region DM-NDA. Each of the plurality of signal lines SGL may have a single body shape, but may include a plurality of portions disposed in different layers. Different portions separated by an insulating layer may be connected through contact holes passing through the insulating layer. In an embodiment, the data lines DL may include a first portion disposed in the display region DM-DA, and a second portion disposed in the non-display region DM-NDA and disposed in a different layer from the first portion, for example. The first portion and the second portion may include different materials and may have different stack structures.

The plurality of signal lines SGL may be electrically connected to the main circuit board MCB shown in FIG. 3 through the pad region PA. In an embodiment, the plurality of signal lines SGL may be disposed in the pad region PA and connected to pad electrodes PD spaced apart in the first direction DR1 through a connection electrode or the like in the first direction, for example. The pad electrodes PD may be disposed on the rear surface of the display panel DP and connected to the flexible circuit board FCB (refer to FIG. 2).

FIG. 6 shows a cross-section of the display module DM corresponding to the pixel PX of FIG. 5.

The pixel driving circuit PC driving a light-emitting element LD may include a plurality of pixel driving elements. The pixel driving circuit PC may include a plurality of transistors S-TFT and O-TFT, and a capacitor Cst. The plurality of transistors S-TFT and O-TFT may include a silicon transistor S-TFT and an oxide transistor O-TFT. FIG. 6 shows a silicon transistor S-TFT and an oxide transistor O-TFT. The pixel driving circuit PC of FIG. 6 is merely one of embodiments, and the components of the pixel driving circuit PC are not necessarily limited thereto. The pixel driving circuit PC may include only one type of transistor from the silicon transistor S-TFT and the oxide transistor O-TFT.

Referring to FIG. 6, the base layer BL is shown as a single layer. The base layer BL may include a synthetic resin such as polyimide. The synthetic resin layer may be applied onto a working substrate (or a carrier substrate) to form the base layer BL. When the display module DM is completed through subsequent processes, the working substrate may be removed.

Referring to FIG. 6, a barrier layer BRL may be disposed on the base layer BL. The barrier layer BRL prevents foreign substances from being introduced from the outside. The barrier layer BRL may include at least one inorganic layer. The barrier layer BRL may include a silicon oxide layer and a silicon nitride layer. Each of these may be provided in plural, and silicon oxide layers and silicon nitride layers may be alternately stacked.

The barrier layer BRL may include a lower barrier layer BRL1 and an upper barrier layer BRL2. A first shielding electrode BML1 may be disposed between the lower barrier layer BRL1 and the upper barrier layer BRL2. The first shielding electrode BML1 may be disposed to correspond to the silicon transistor S-TFT. The first shielding electrode BML1 may include metal, such as molybdenum.

The first shielding electrode BML1 may receive a bias voltage. The first shielding electrode BML1 may receive the first power voltage. The first shielding electrode BML1 may block an electric potential caused by a polarization phenomenon from affecting the silicon transistor S-TFT. The first shielding electrode BML1 may block external light from reaching the silicon transistor S-TFT. In an embodiment of the inventive concept, the first shielding electrode BML1 may be a floating electrode in a form isolated from other electrodes or wires.

A buffer layer BFL may be disposed on the barrier layer BRL. The buffer layer BFL may prevent diffusion of metal atoms or impurities from the base layer BL into a first semiconductor pattern SC1 disposed thereabove. The buffer layer BFL may include at least one inorganic layer. The buffer layer BFL may include a silicon oxide layer and a silicon nitride layer.

The first semiconductor pattern SC1 may be disposed on the buffer layer BFL. The first semiconductor pattern SC1 may include a silicon semiconductor. In an embodiment, the silicon semiconductor may include amorphous silicon, polycrystalline silicon, or the like, for example. In an embodiment, the first semiconductor pattern SC1 may include low-temperature polysilicon, for example.

The first semiconductor pattern SC1 may have different electrical properties according to with/without doping. The first semiconductor pattern SC1 may include a first region having relatively high conductivity and a second region having relatively low conductivity. The first region may be doped with an N-type dopant or a P-type dopant. A P-type transistor may include a doped region doped with the P-type dopant, and an N-type transistor may include a doped region doped with the N-type dopant. The second portion may be a non-doped region or may be doped in a lower concentration than the first region. In the illustrated embodiment, the first semiconductor pattern SC1 may be an N-type transistor.

A first region has greater conductivity than a second region, and may substantially serve as an electrode or a signal line. The second region may substantially correspond to a channel region (or an active region) of the transistor. That is, a portion of the first semiconductor pattern SC1 may be a channel of the transistor, another portion may be a source or drain of the transistor, and a remaining portion may be a connection electrode or a connection signal line.

A source region SE1, a channel region AC1 (or an active region), and a drain region DE1 of the silicon transistor S-TFT may be formed from the first semiconductor pattern SC1. The source region SE1 and the drain region DE1 may extend in opposite directions from the channel region AC1 in a cross-section.

The first insulating layer 10 may be disposed on the buffer layer BFL. The first insulating layer 10 may cover the first semiconductor pattern SC1. The first insulating layer 10 may be an inorganic layer. The first insulating layer 10 may be a single-layered silicon oxide layer. The first insulating layer 10 as well as an inorganic layer of the circuit layer DP-CL, which will be described later may have a single-layer structure or a multi-layer structure, and may include at least one of the above materials, but the inventive concept is not limited thereto.

A gate GT1 of the silicon transistor S-TFT is disposed on the first insulating layer 10. The gate GT1 may be a portion of a metal pattern. The gate GT1 overlaps the channel region AC1. In the process of doping the first semiconductor pattern SC1, the gate GT1 may be a mask. A first electrode CE10 of a storage capacitor Cst is disposed on the first insulating layer 10. Unlike what is shown in FIG. 6, the first electrode CE10 may have a single body shape with the gate GT1.

A second insulating layer 20 may be disposed on the first insulating layer 10 and may cover the gate GT1. In an embodiment of the inventive concept, an upper electrode overlapping the gate GT1 may be further disposed on the second insulating layer 20. A second electrode CE20 overlapping the first electrode CE10 may be disposed on the second insulating layer 20. The upper electrode may have a single body shape with the second electrode CE20 in a plan view.

A second shielding electrode BML2 is disposed on the second insulating layer 20. The second shielding electrode BML2 may be disposed to correspond to the oxide transistor O-TFT. In an embodiment of the inventive concept, the second shielding electrode BML2 may not be provided. In an embodiment of the inventive concept, the first shielding electrode BML1 may extend to a bottom of the oxide transistor O-TFT, thereby replacing the second shielding electrode BML2.

A third insulating layer 30 may be disposed on the second insulating layer 20. A second semiconductor pattern SC2 may be disposed on the third insulating layer 30. The second semiconductor pattern SC2 may include the channel region AC2 of the oxide transistor O-TFT. The second semiconductor pattern SC2 may include a metal oxide semiconductor. The second semiconductor pattern SC2 may include a transparent conductive oxide (“TCO”) such as indium tin oxide (“ITO”), indium zinc oxide (“IZO”), indium gallium zinc oxide (“IGZO”), zinc oxide (ZnOx), indium oxide (In2O3), or the like.

The metal oxide semiconductor may include a plurality of regions SE2, AC2, and DE2 divided according to whether transparent conductive oxides are reduced. A region in which transparent conductive oxides are reduced (hereinafter, reduction region) has greater conductivity than a region in which the transparent conductive oxide are not reduced (hereinafter, non-reduction region). The reduction region substantially serves as a source/drain of transistors or signal lines. The non-reduction region substantially corresponds to a semiconductor region (or a channel) of transistors. That is, a portion of the second semiconductor pattern SC2 may be a semiconductor region of transistors, another partial region may be a source region SE2/drain region DE2 of transistors, and a remaining region may be a signal transmission region.

A fourth insulating layer 40 may be disposed on the third insulating layer 30. As shown in FIG. 6, the fourth insulating layer 40 may cover the second semiconductor pattern SC2. In an embodiment of the inventive concept, the fourth insulating layer 40 may be an insulation pattern overlapping the gate GT2 of the oxide transistor O-TFT and be exposed by the source region SE2 and the drain region DE2 of the oxide transistor O-TFT.

A gate GT2 of the oxide transistor O-TFT is disposed on the fourth insulating layer 40. The gate GT2 of the oxide transistor O-TFT may be a portion of a metal pattern. The gate GT2 of the oxide transistor O-TFT overlaps the channel region AC2.

A fifth insulating layer 50 may be disposed on the fourth insulating layer 40, and the fifth insulating layer 50 may cover the gate GT2. Each of the first insulating layer 10 to the fifth insulating layer 50 may be an inorganic layer.

A first connection pattern CNP1 and a second connection pattern CNP2 may be disposed on the fifth insulating layer 50. The first connection pattern CNP1 and the second connection pattern CNP2 are formed through the same process, and may thus have the same material and the same stack structure as each other. The first connection pattern CNP1 may be connected to drain region DE1 of the silicon transistor S-TFT through a first pixel contact hole PCH1 passing through the first to fifth insulating layers 10, 20, 30, 40, and 50. The second connection pattern CNP2 may be connected to the source region SE2 of the oxide transistor O-TFT through a second pixel contact hole PCH2 passing through the fourth and fifth insulating layers 40 and 50. The connection relationship between the first connection pattern CNP1 and the second connection pattern CNP2 for the silicon transistor S-TFT and the oxide transistor O-TFT is not necessarily limited thereto.

A sixth insulating layer 60 may be disposed on the fifth insulating layer 50. A third connection pattern CNP3 may be disposed on the sixth insulating layer 60. The third connection pattern CNP3 may be connected to the first connection pattern CNP1 through a third pixel contact hole PCH3 passing through the sixth insulating layer 60. A data line DL may be disposed on the sixth insulating layer 60. A seventh insulating layer 70 is disposed on the sixth insulating layer 60 and may cover the third connection pattern CNP3 and the data line DL. The third connection pattern CNP3 and the data line DL are formed through the same process, and may thus have the same material and the same stack structure as each other. Each of the sixth insulating layer 60 and the seventh insulating layer 70 may be an organic layer.

The first shielding electrode BML1, the gate GT1 of the silicon transistor S-TFT, the second electrode CE20, and the gate GT2 of the oxide transistor O-TFT may include molybdenum (Mo) having satisfactory heat resistance, an alloy including or consisting of molybdenum, titanium (Ti), or an alloy including or consisting of titanium. The first connection pattern CNP1 and the second connection pattern CNP2 may include aluminum having relatively high electrical conductivity. The first connection pattern CNP1 and the second connection pattern CNP2 may have a three-layered structure in which titanium/aluminum/titanium are stacked.

The light-emitting element LD may include an anode AE (or a first electrode), an emission layer EL, and a cathode CE (or a second electrode). The anode AE of the light-emitting element LD may be disposed on the seventh insulating layer 70. The anode AE may be a transmissive electrode, a transflective electrode, or a reflective electrode. The anode AE may include a stack structure in which ITO/Ag/ITO are sequentially stacked. Positions of the anode AE and the cathode CE may be interchanged.

The pixel defining film PDL may be disposed on the seventh insulating layer 70. The pixel defining film PDL may be an organic layer. The pixel defining film PDL may have light absorption properties, and for example, the pixel defining film PDL may be black in color. The pixel defining film PDL may include a black coloring agent. The black coloring agent may include a black dye and a black pigment. The black coloring agent may include carbon black, a metal such as chromium, or an oxide thereof. The pixel defining film PDL may correspond to a light-blocking pattern having light-blocking properties.

The pixel defining film PDL may cover a portion of the anode AE. In an embodiment, an opening PDL-OP exposing a portion of the anode AE may be defined in the pixel defining film PDL, for example. A light-emitting region LA may be defined to correspond to the opening PDL-OP. In an embodiment of the inventive concept, a hole control layer may be disposed between the anode AE and the emission layer EL. The hole control layer may include a hole transport layer, and may further include a hole injection layer. An electron control layer may be disposed between the emission layer EL and the cathode CE. The electron control layer may include an electron transport layer, and may further include an electron injection layer.

The encapsulation layer TFE may cover the light-emitting element LD. The encapsulation layer TFE may include a first encapsulation insulating layer IL1, a second encapsulation insulating layer IL2, and a third encapsulation insulating layer IL3. However, the inventive concept is not limited thereto, and the encapsulation layer TFE may further include a plurality of inorganic layers and organic layers.

The first encapsulation insulating layer IL1 may be an inorganic layer. The first encapsulation insulating layer IL1 may prevent external moisture or oxygen from penetrating into the light-emitting element LD. In an embodiment, the first encapsulation insulating layer IL1 may include silicon nitride, silicon oxide, or any combinations thereof, for example. The first encapsulation insulating layer IL1 may be formed through a chemical vapor deposition process.

The second encapsulation insulating layer IL2 may be an organic layer. The second encapsulation insulating layer IL2 may be disposed on the first encapsulation insulating layer IL1 and may contact the first encapsulation insulating layer IL1. The second encapsulation insulating layer IL2 may provide a flat surface on the first encapsulation insulating layer IL1. A curvature formed on an upper surface of the first encapsulation insulating layer IL1 or particles on the first encapsulation insulating layer IL1 may be covered by the second encapsulation insulating layer IL2 to prevent a surface state of the upper surface of the first encapsulation insulating layer IL1 from affecting components formed on the second encapsulation insulating layer IL2. In addition, the second encapsulation insulating layer IL2 may relieve stress between layers in contact. The second encapsulation insulating layer IL2 may be formed through a solution process such as spin coating, slit coating, or inkjet process.

The third encapsulation insulating layer IL3 is disposed on the second encapsulation insulating layer IL2 and covers the second encapsulation insulating layer IL2. The third encapsulation insulating layer IL3 may be stably formed on a relatively flat surface rather than being disposed on the first encapsulation insulating layer IL1. The third encapsulation insulating layer IL3 seals moisture released from the second encapsulation insulating layer IL2 and prevents the moisture from flowing into the outside.

The third encapsulation insulating layer IL3 may be optically transparent. In an embodiment, the third encapsulation insulating layer IL3 may have a visible light transmittance of about 90% or greater, for example. The third encapsulation insulating layer IL3 may have a relatively higher light transmittance than the first encapsulation insulating layer IL1. The third encapsulation insulating layer IL3 may be an inorganic layer. The third encapsulation insulating layer IL3 may include silicon oxide (SiOx) or silicon oxynitride (SiON). The third encapsulation insulating layer IL3 may be formed through a chemical vapor deposition process. Each of the first encapsulation insulating layer IL1, the second encapsulation insulating layer IL2, and the third encapsulation insulating layer IL3 may include a plurality of layers and is not limited to a particular embodiment.

The input sensing layer ISL may include at least one conductive layer (or at least one sensor conductive layer) and at least one insulating layer (or at least one sensor insulating layer). In the illustrated embodiment, the input sensing layer ISL may include a first sensing insulating layer IS-IL1, a first conductive layer ICL1, a second insulating layer IS-IL2, a second conductive layer ICL2, and a third insulating layer IS-IL3. FIG. 6 briefly shows a conductive line of the first conductive layer ICL1 and a conductive line of the second conductive layer ICL2.

The first sensing insulating layer IS-IL1 may be directly disposed on the display panel DP. The first sensing insulating layer IS-IL1 may be an inorganic layer including at least any one of silicon nitride, silicon oxynitride, or silicon oxide. The first conductive layer ICL1 and the second conductive layer ICL2 each may have a single-layered structure or may have a multi-layered structure stacked along the third direction DR3. The first conductive layer ICL1 and the second conductive layer ICL2 may include conductive lines that define an electrode in the form of a mesh. The conductive line of the first conductive layer ICL1 and the conductive line of the second conductive layer ICL2 may or may not be connected through a contact hole passing through the second insulating layer IS-IL2. A connection relationship between the conductive line of the first conductive layer ICL1 and the conductive line of the second conductive layer ICL2 may be determined according to the type of sensors formed as the input sensing layer ISL.

The first conductive layer ICL1 and the second conductive layer ICL2 having a single-layer structure may include a metal layer or a transparent conductive layer. The metal layer may include molybdenum, silver, titanium, copper, aluminum, or any alloys thereof. The transparent conductive layer may include a transparent conductive oxide such as indium tin oxide (“ITO”), indium zinc oxide (“IZO”), zinc oxide (ZnOx), or indium zinc tin oxide (“IZTO”). In addition, the transparent conductive layer may include a conductive polymer such as poly(3,4-ethylenedioxythiophene) (“PEDOT”), a metal nanowire, graphene, or the like.

The first conductive layer ICL1 and the second conductive layer ICL2 having a multi-layer structure may include metal layers. The metal layers may have a three-layer structure of, e.g., titanium/aluminum/titanium. The multi-layered conductive layer may include at least one metal layer and at least one transparent conductive layer. The second insulating layer IS-IL2 may be disposed between the first conductive layer ICL1 and the second conductive layer ICL2. The third insulating layer IS-IL3 may cover the second conductive layer ICL2. In an embodiment of the inventive concept, the third insulating layer IS-IL3 may not be provided. The second insulating layer IS-IL2 and the third insulating layer IS-IL3 may include an inorganic layer or an organic layer.

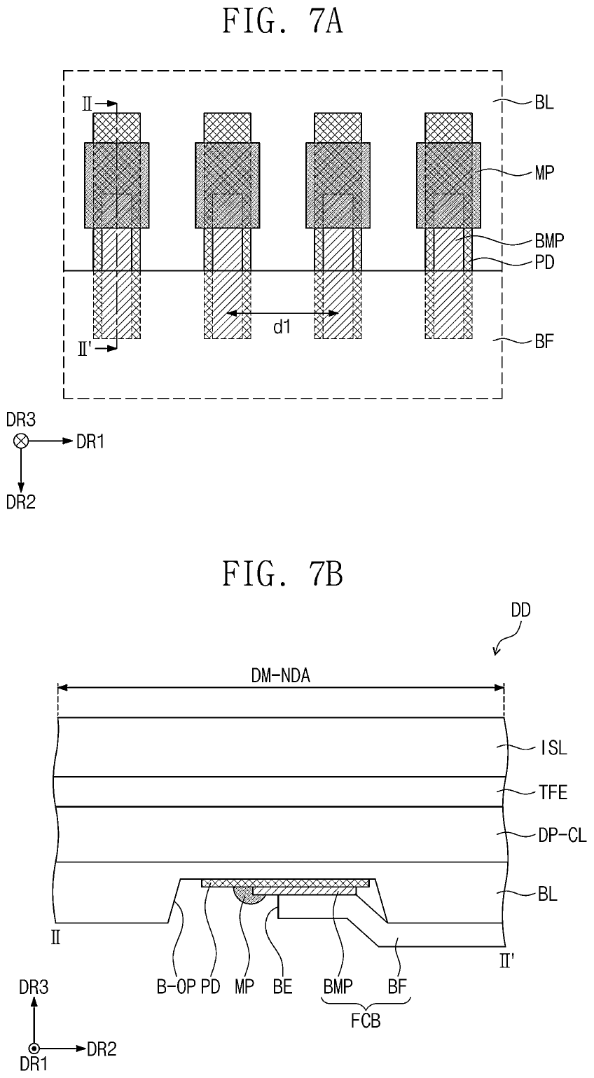

FIG. 7A is a view enlarging a portion of an embodiment of a display device according to the inventive concept. FIG. 7B is a cross-sectional view of a base layer, taken along line II-II′ of FIG. 7A. Hereinafter, descriptions overlapping those described previously will not be provided.

Referring to FIGS. 7A and 7B, a base opening B-OP may be defined in the base layer BL. The pad electrodes PD may be disposed in the base opening B-OP. Although not shown, the pad electrodes PD may be electrically connected to connection electrode disposed on the base layer BL through a contact hole. The pad electrodes PD may be electrically connected to the data line DL shown in FIG. 6 through a connection electrode. The pad electrodes PD may be exposed to the outside through the base opening B-OP. The pad electrodes PD may overlap the non-display region DM-NDA (refer to FIG. 2). In an embodiment, the pad electrodes PD may be disposed in the pad region PA shown in FIG. 2, for example.

Referring to FIG. 7A, the pad electrodes PD may extend in the second direction DR2 and be arranged along the first direction DR1. Distances d1 between respective centers of the adjacent pad electrodes PD arranged along the first direction DR1 may be equal to each other. In an embodiment, the distances d1 between the pad electrodes PD arranged along the first direction DR1 may be about 10 μm to about 20 μm, for example.

The flexible circuit board FCB may include a base film BF and a bump electrode BMP disposed on the base film BF and partially exposed from an edge BE of the base film BF. The bump electrode BMP may overlap the pad electrodes PD in a plan view. The bump electrode BMP may contact the pad electrodes PD and may be electrically connected to the pad electrodes PD. A plurality of bump electrodes BMP may be provided. The plurality of bump electrodes BMP may be formed corresponding to the pad electrodes PD. One bump electrode BMP may correspond to one pad electrode PD. The plurality of bump electrodes BMP may extend in the first direction DR1 and be arranged along the second direction DR2.

The bump electrodes BMP may be electrically connected to the pad electrodes PD. Specifically, the display device DD may further include a metal pattern MP electrically connecting the bump electrodes BMP and the pad electrodes PD. The metal pattern MP contacts the pad electrodes PD and the bump electrodes BMP exposed from the edge BE of the base film BF to electrically connect the pad electrodes PD and the bump electrodes BMP.

A plurality of metal patterns MP may be provided to correspond to a plurality of pad electrodes PD. The plurality of metal patterns MP may each be a pattern in which metal ink is cured. The metal patterns MP may include solder paste. The metal patterns MP may be formed from metal ink including or consisting of silver or copper. The metal patterns MP may be disposed on each pad electrode PD. The metal patterns MP may be formed by curing and then patterning metal ink. The metal patterns MP may be formed at a relatively low temperature, and may electrically connect and concurrently bond the pad electrodes PD and the bump electrodes BMP without a pressurizing process at a relatively high temperature.

Although not shown, an adhesive layer may be further disposed between the pad electrodes PD and the bump electrodes BMP and between the base film BF and the base layer BL. In an embodiment, the adhesive layer may include an insulating material. In this case, the pad electrodes PD and the bump electrodes BMP may be electrically connected only through the metal pattern MP.

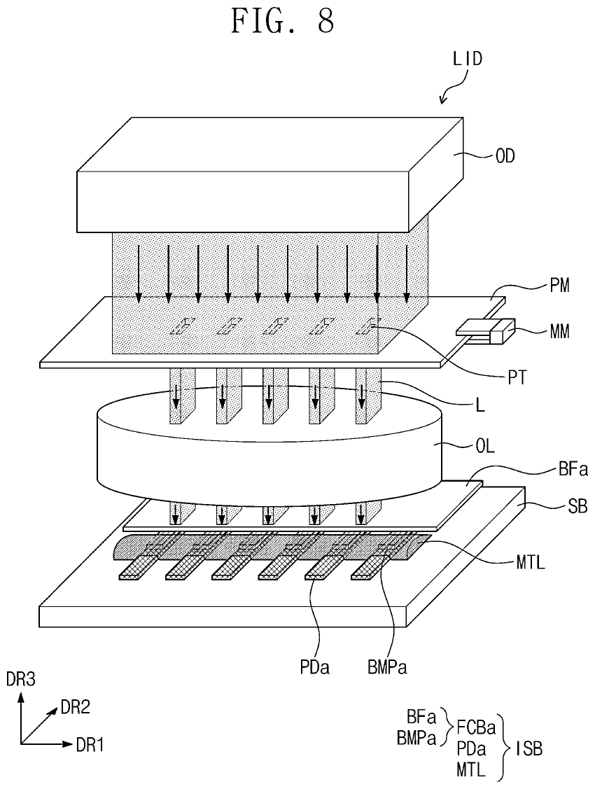

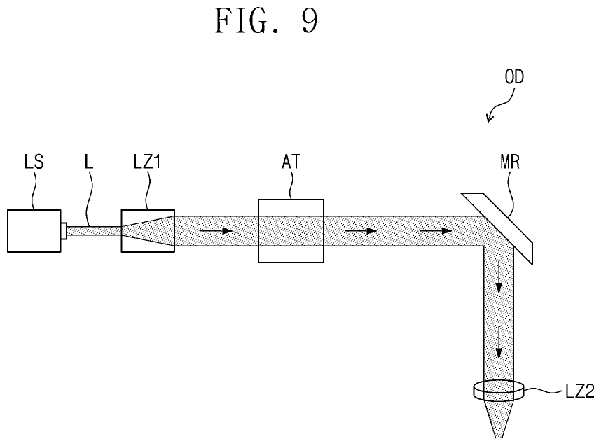

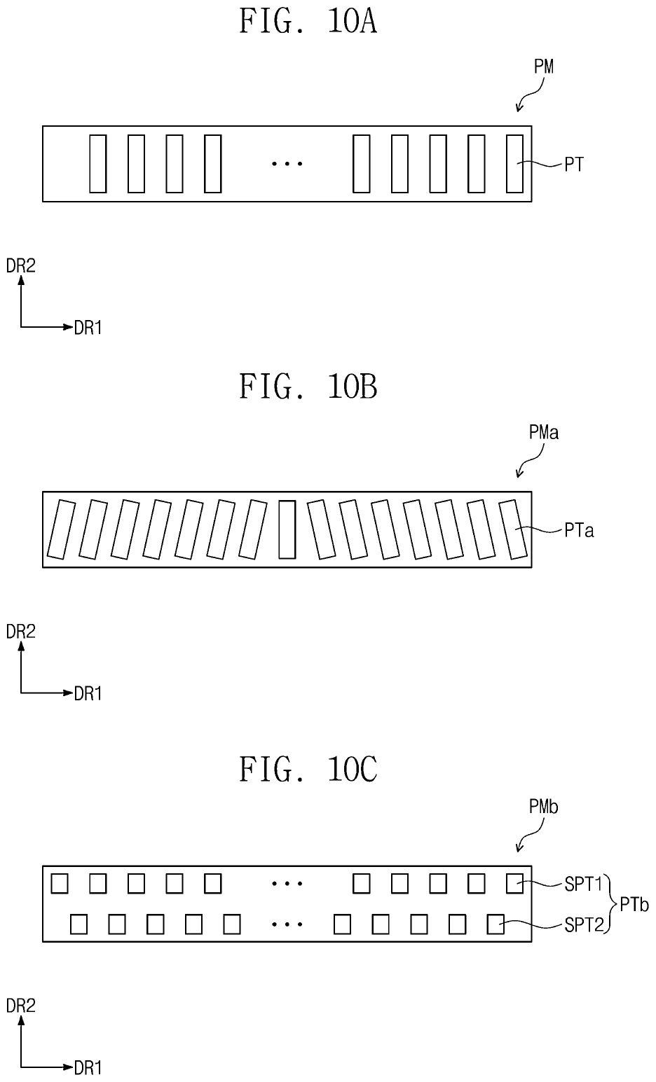

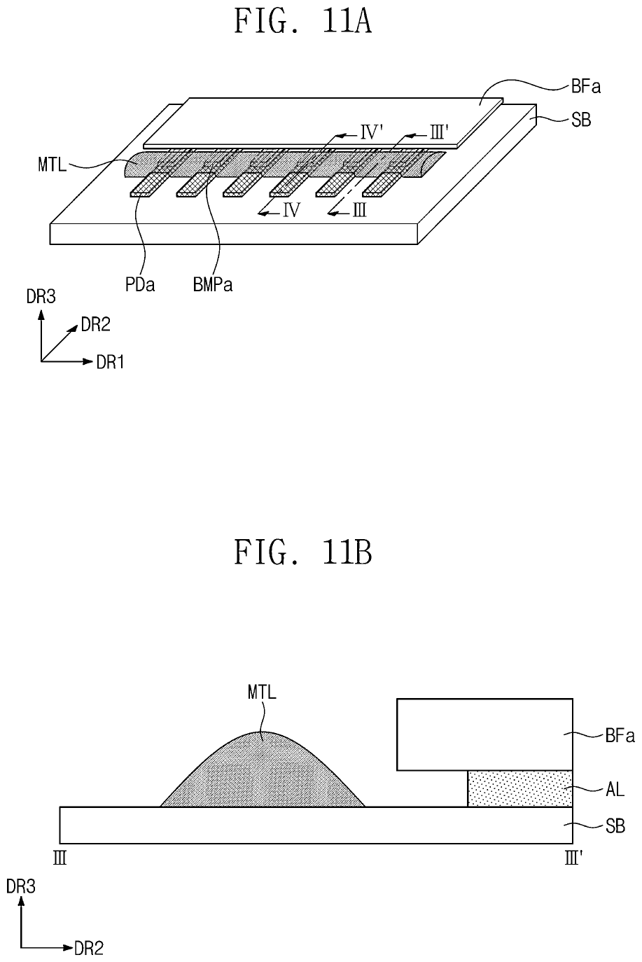

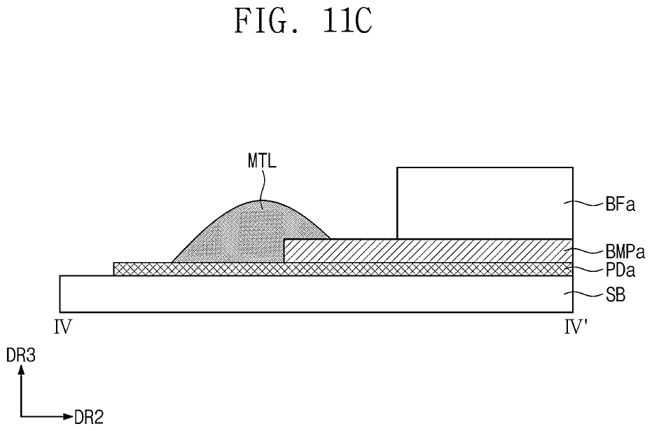

FIG. 8 is a perspective view of an embodiment of a laser irradiation device according to the inventive concept. FIG. 9 is a cross-sectional view showing components of an optical system shown in FIG. 8. FIG. 10A is a plan view of a pattern mask shown in FIG. 8. FIGS. 10B and 10C are plan views showing another embodiment of the pattern mask shown in FIG. 8. FIGS. 11A to 11C are views showing an irradiation target shown in FIG. 8. With reference to FIGS. 8 to 11C, a laser irradiation device LID in an embodiment of the inventive concept will be described. An irradiation target ISB may correspond to some components of the display device DD shown in FIG. 7B.

Referring to FIG. 8, the laser irradiation device LID in an embodiment of the inventive concept may include an optical system OD emitting an intense light (e.g., laser L), a pattern mask PM including a plurality of patterns on which the laser L emitted from an optical system OD is incident and through which the laser L passes, and an optical lens OL. The irradiation target ISB may be irradiated with the laser L through the laser irradiation device LID according to the inventive concept. In an embodiment, a metal layer MTL disposed on the substrate SB may be irradiated with the laser L through the laser irradiation device LID in an embodiment of the inventive concept, for example. The optical system OD may be placed on an upper portion of the laser irradiation device LID, and the pattern mask PM may be placed below the optical system OD. The optical lens OL may be disposed between the pattern mask PM and the irradiation target ISB.

Referring to FIGS. 8 and 9, the optical system OD placed on the upper portion of the laser irradiation device LID may include a light source LS, a first lens LZ1, an attenuator AT, a reflection mirror MR, and a second lens LZ2.

The laser L may be emitted from the light source LS. The laser L may be directed toward the first lens LZ1 disposed adjacent to the light source LS. In an embodiment of the inventive concept, the laser L may have a wavelength of about 200 nanometers (nm) to about 400 nm. In an embodiment, the laser L may have a wavelength of about 248 nm to about 266 nm, for example. However, the inventive concept is not limited thereto.

The first lens LZ1 may receive the laser L from the light source LS. The first lens LZ1 may regulate the size of the laser L emitted from the light source LS. That is, the first lens LZ1 may control the diameter or energy density of the laser L. The first lens LZ1 may be a convex lens. The laser L subjected to passing through the first lens LZ1 may be converged by the first lens LZ1. However, the inventive concept is not limited thereto, and the first lens LZ1 may consist of two or more lenses.

The attenuator AT may be disposed on a path of the laser L subjected to passing through the first lens LZ1. That is, the laser beam L converged through the first lens LZ1 may be provided to the attenuator AT. The attenuator AT may alter an amplitude of the laser L provided to the attenuator AT. However, the attenuator AT only reduces the amplitude of the laser L and does not alter a signal waveform of the laser L. That is, the attenuator AT may lower a signal level of the laser L.

The reflection mirror MR may be disposed on the path of the laser L subjected to passing through the attenuator AT. The reflection mirror MR may regulate an irradiation direction of the laser L such that the laser L is emitted to the pattern mask PM shown in FIG. 8. In an embodiment, the reflection mirror MR may alter the irradiation direction of the laser L from the second direction DR2 to the third direction DR3, for example.

The second lens LZ2 may receive the laser L subjected to passing through the reflection mirror MR. The second lens LZ2 may regulate the size of the laser L emitted to the second lens LZ2 in the same way as the first lens LZ1. That is, the second lens LZ2 may control the diameter or energy density of the laser L. The second lens LZ2 may be a convex lens. The laser L subjected to passing through the second lens LZ2 may be converged by the second lens LZ2. However, the inventive concept is not limited thereto, and the second lens LZ2 may include a plurality of lenses. The second lens LZ2 may be regulated to have uniform energy in a region in which the laser L is emitted by adjusting a focal distance. The laser L subjected to passing through the second lens LZ2 may be emitted to the pattern mask PM shown in FIG. 8.

Referring to FIGS. 8 and 10A, the pattern mask PM may be disposed below the optical system OD. The pattern mask PM may be disposed between the optical system OD and the irradiation target ISB, and may be disposed parallel to a substrate SB of the irradiation target ISB. Specifically, the pattern mask PM may include a plane extending in the first direction DR1 and the second direction DR2. The pattern mask PM may receive the laser L emitted from the optical system OD. In an embodiment of the inventive concept, the laser L emitted from the optical system OD and incident on the pattern mask PM may include a laser line beam. However, the inventive concept is not limited thereto, and the laser L may include a laser area beam. In addition, the laser L emitted from the light source LS shown in FIG. 9 may itself include a laser line beam.

The pattern mask PM may be damaged by the laser L emitted to the pattern mask PM, and accordingly, may have an ablation threshold with a predetermined size or greater. In an embodiment, the pattern mask PM may have an ablation threshold of about 100 millijoules per square centimeter (mJ/cm²) or greater, for example.

The pattern mask PM may include a plurality of patterns PT. The plurality of patterns PT may be disposed to overlap the metal layer MTL in a plan view. The plurality of patterns PT may extend in the second direction DR2 and be arranged in the first direction DR1. The plurality of patterns PT may each have the same size, and distances between adjacent patterns PT may also be the same.

The plurality of patterns PT may not overlap the plurality of pads PDa in a plan view. The plurality of patterns PT may serve to pattern the metal layer MTL by patterning the laser L emitted to the pattern mask PM. The laser L patterned corresponding to the shape of the plurality of patterns PT may be emitted to the metal layer MTL. That is, the metal layer MTL overlapping a region that not overlaps the plurality of pads PDa may be irradiated with the laser L to pattern the metal layer MTL. Accordingly, distances between the plurality of patterns PT in the first direction DR1 may be equal to distances between the plurality of pads PDa in the first direction DR1.

FIG. 10B is a view showing another embodiment of the pattern mask PM shown in FIG. 8.

Referring to FIG. 10B, a pattern mask PMa may include a plurality of patterns PTa. The plurality of patterns PTa may be formed to incline at a predetermined angle with respect to the second direction DR2 when compared to the plurality of pads PDa in a plan view. As shown, among the plurality of patterns PTa, the pattern PTa disposed in the center may have the same shape as that of the patterns PT shown in FIG. 10A, and with respect to the pattern PTa disposed in the center, patterns PTa may be formed to incline in a direction toward the pattern PTa disposed in the center.

Referring to FIG. 10C, the pattern mask PMb may include a plurality of patterns PTb. The plurality of patterns PTb may include first sub-patterns SPT1 and second sub-patterns SPT2, which are spaced apart in the second direction DR2. The first sub-patterns SPT1 and the second sub-patterns SPT2 may each be arranged in the first direction DR1. When viewed in the second direction DR2, the first sub-patterns SPT1 and the second sub-patterns SPT2 may be arranged alternately in the first direction DR1. Specifically, one of the second sub-patterns SPT2 may be disposed between two adjacent first sub-patterns SPT1, and one of the first sub-patterns SPT1 may be disposed between two adjacent second sub-patterns SPT2.

Referring back to FIG. 8, a moving module MM that moves the pattern mask PM in the third direction DR3 may be further included. While the irradiation target ISB is irradiated with the laser L, the moving module MM may move the pattern mask PM in the third direction DR3. Accordingly, as the pattern mask PM moves in the third direction DR3, an area (also referred to as an irradiation area) of the laser L patterned by passing through the pattern mask PM may gradually increase. That is, the moving module MM may control the area of the laser L emitted to the metal layer MTL by moving the pattern mask PM in the third direction DR3.

The optical lens OL may be further disposed between the pattern mask PM and the irradiation target ISB. The optical lens OL may converge the laser L subjected to passing through the pattern mask PM. That is, the optical lens OL may include a convex lens. In an embodiment of the inventive concept, the optical lens OL may include a chromatic aberration lens. In an embodiment, the optical lens OL may be a lens set to prevent chromatic aberration, for example. Accordingly, the laser L subjected to passing through the optical lens OL may be uniformly emitted to the irradiation target ISB.

FIG. 11A is a perspective view of the irradiation target ISB. FIG. 11B is a cross-sectional view of the irradiation target ISB taken along line III-III′ of FIG. 11A. FIG. 11B is a cross-sectional view of the irradiation target ISB taken along line IV-IV′ of FIG. 11A.

Referring to FIGS. 8 and 11A, the irradiation target ISB may include a substrate SB, a plurality of pads PDa disposed on the substrate SB, a flexible circuit board FCBa, and a metal layer MTL disposed on the plurality of pads PDa and the flexible circuit board FCBa. The flexible circuit board FCBa may include a base film BFa and a bump electrode BMPa. The substrate SB, the plurality of pads PDa, and the flexible circuit board FCBa shown in FIG. 11A may correspond to the base layer BL, the plurality of pads PD, and the flexible circuit board FCB shown in FIG. 7B. Therefore, overlapping descriptions will not be provided.

Referring to FIGS. 11A to 11C, the metal layer MTL may be disposed on the plurality of pads PD and the bump electrode BMPa. The metal layer MTL may be unitary with the plurality of pads PD and the bump electrode BMPa. The laser irradiation device LID (refer to FIG. 8) in an embodiment of the inventive concept intends to irradiate the metal layer MTL disposed in a region non-overlapping the plurality of pads PD and the bump electrode BMPa with a laser so that the metal layer MTL forms to be disposed only in a region overlapping the plurality of pads PD and the bump electrode BMPa.

Referring to FIG. 11B, an adhesive layer may not be provided. An adhesive layer AL may be disposed between the substrate SB and the base film BFa. The substrate SB and the base film BFa may be bonded through the adhesive layer AL. In an embodiment of the inventive concept, the adhesive layer AL may include a non-conductive material. In an embodiment, the adhesive layer AL may be disposed between the substrate SB and the base film BFa in the form of a non-conductive film, for example.

Referring to FIG. 11C, the metal layer MTL may overlap the plurality of pads PD and the bump electrode BMPa in a plan view to be disposed on the plurality of pads PD and the bump electrode BMPa. It may be electrically connected. The metal layer MTL is formed to overlap only the plurality of pads PD and the bump electrode BMPa in a plan view, and accordingly, the plurality of pads PD and the bump electrode BMPa may be electrically connected.

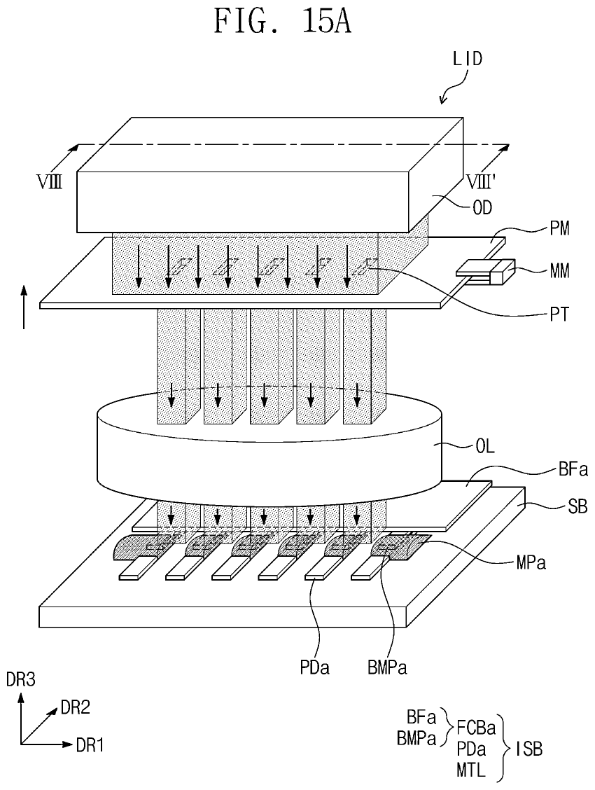

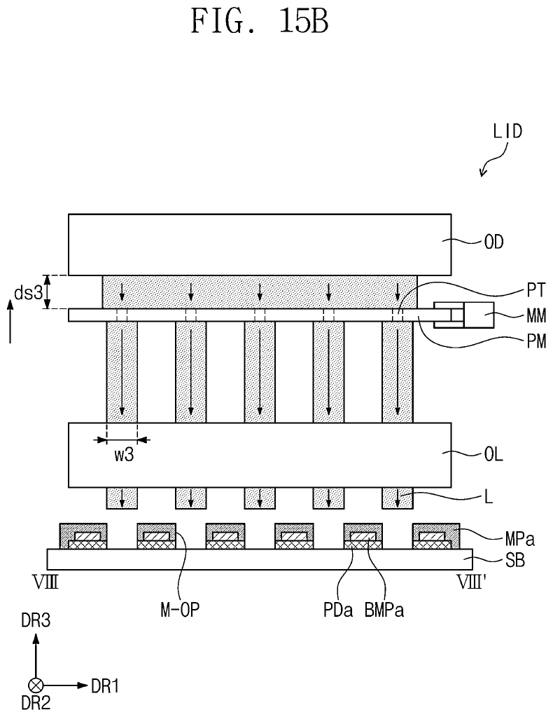

Referring to FIGS. 8 and 11A to 11C, the laser L subjected to passing through the optical lens OL may be emitted to the metal layer MTL non-overlapping the plurality of pads PD and the bump electrode BMPa. When patterning the metal layer MTL including a non-uniform thickness using the laser L, the substrate SB may also be patterned by the laser L, and may thus be damaged. The laser irradiation device LID in an embodiment of the inventive concept controls an area in which the laser L is emitted to the metal layer MTL having a non-uniform thickness through the moving module MM that moves the pattern mask PM in the third direction DR3, and may thus pattern the metal layer MTL without damaging the substrate SB. A process of forming a metal pattern MP (FIG. 15A) using the laser irradiation device LID (refer to FIG. 8) in an embodiment of the inventive concept will be described later.

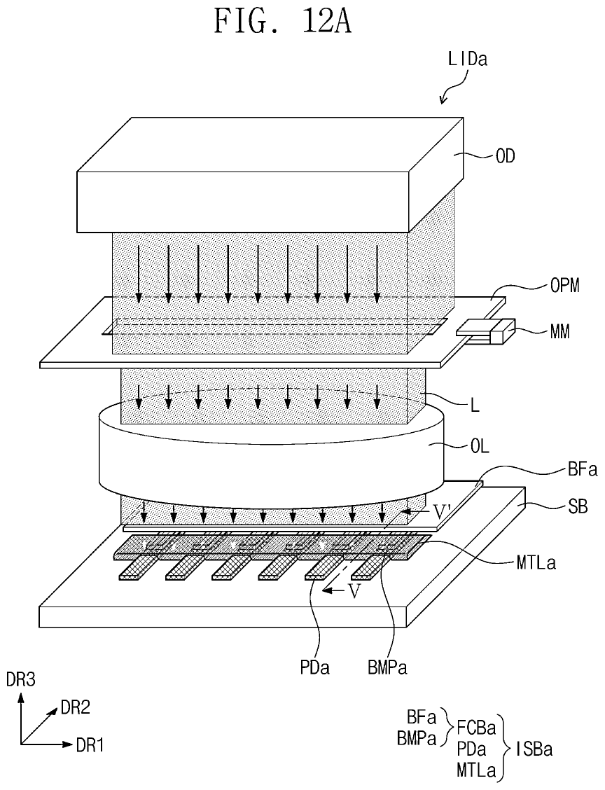

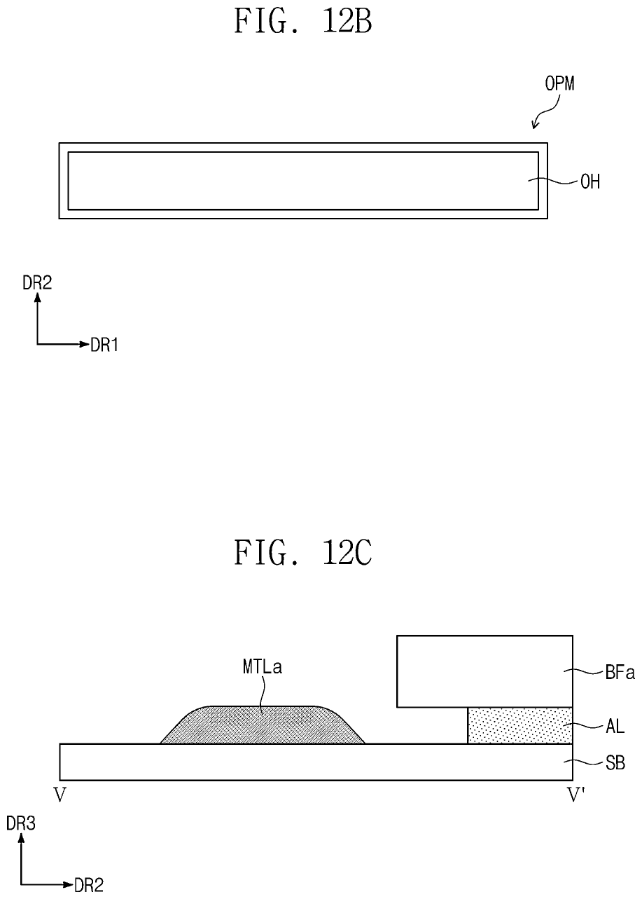

FIG. 12A is a perspective view of an embodiment of a laser irradiation device according to the inventive concept. FIG. 12B is a plan view of an open mask shown in FIG. 12A. FIG. 12C is a cross-sectional view taken along line V-V′ of FIG. 12A. Content overlapping what was described previously will not be provided.

Referring to FIGS. 12A and 12B, a laser irradiation device LIDa in an embodiment of the inventive concept may include an open mask OPM. Unlike the pattern mask PM shown in FIG. 8, the open mask OPM may include an open hole OH instead of a pattern PT. The laser L emitted from the laser irradiation device LIDa in an embodiment of the inventive concept may be emitted to an open mask OPM including the open hole OH. The laser L emitted to the open mask OPM may be emitted from the open mask OPM corresponding to the shape of the open hole OH. The laser L emitted from the open mask OPM may pass through the optical lens OL and be emitted to a metal layer MTLa.

An irradiation target ISBa may include a substrate SB, a plurality of pads PDa disposed on the substrate SB, a flexible circuit board FCBa, and a metal layer MTLa disposed on the plurality of pads PDa and the flexible circuit board FCBa. The flexible circuit board FCBa may include a base film BFa and a bump electrode BMPa. The irradiation target ISBa may be irradiated with the laser L through the laser irradiation device LIDa according to the inventive concept. In an embodiment, the metal layer MTLa disposed on the substrate SB may be irradiated with the laser L through the laser irradiation device LIDa in an embodiment of the inventive concept, for example.

When patterning the metal layer MTLa having a non-uniform thickness, the substrate SB is also patterned together after the patterning, which may cause damage to the substrate SB. The laser irradiation device LIDa in an embodiment of the inventive concept controls an area in which the laser L is emitted to the metal layer MTLa having a non-uniform thickness through the moving module MM that moves the open mask OPM in the third direction DR3, and may thus etch an upper surface of the metal layer MTLa to be flat without damaging the substrate SB. That is, the open mask (also referred to as a planarization mask) OPM may planarize the metal layer MTLa before forming the plurality of metal patterns MP. Accordingly, even when the metal layer MTLa is patterned using a laser scanning method, damage to the substrate SB may not be caused.

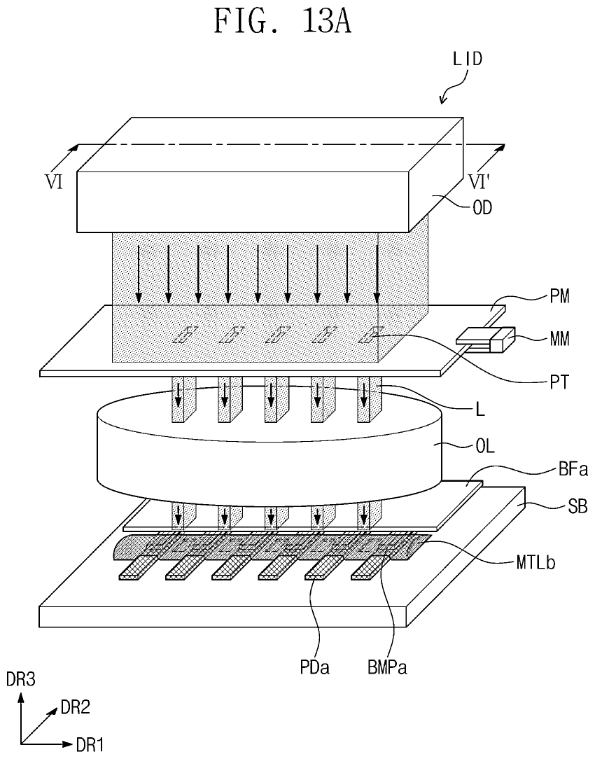

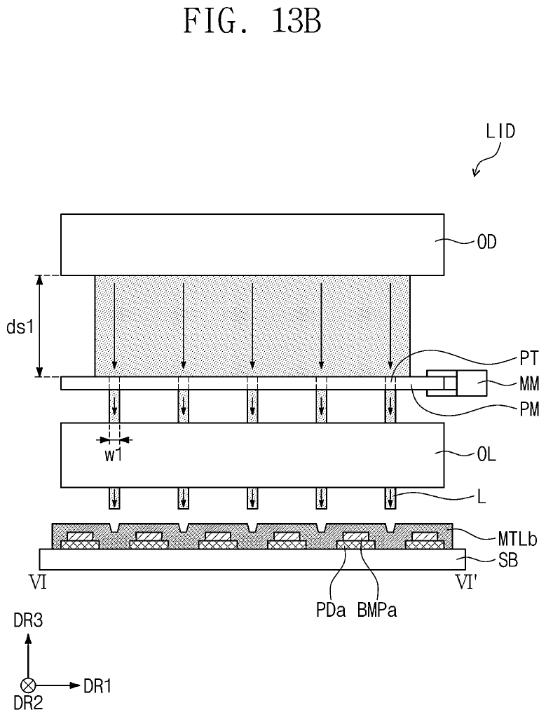

FIGS. 13A to 15B are views showing an embodiment of a process of forming a metal pattern using a laser irradiation device according to the inventive concept. Hereinafter, content overlapping those described previously will not be given.

FIG. 13A is a perspective view of an embodiment of the laser irradiation device LID according to the inventive concept. FIG. 13B is a cross-sectional view of the irradiation target ISB taken along line VI-VI′ of FIG. 13A.

Referring to FIGS. 13A and 13B, the laser L emitted from the optical system OD may be incident on the pattern mask PM including a plurality of patterns PT. The laser L patterned corresponding to the shape of the plurality of patterns PT may be emitted to the metal layer MTLb. The laser L is emitted to the metal layer MTLb, and accordingly, the metal layer MTLb may be etched corresponding to an area in which the laser L is emitted. That is, as shown in FIG. 13B, a portion of the metal layer MTLb may be etched corresponding to a width w1 of the laser L subjected to passing through the pattern mask PM. FIGS. 13A and 13B are views showing a case in which the optical system OD and the pattern mask PM form a first distance ds1. When the optical system OD and the pattern mask PM form the first distance ds1, the width w1 of the laser L subjected to passing through the pattern mask PM may be substantially the same as that of the plurality of patterns PT.

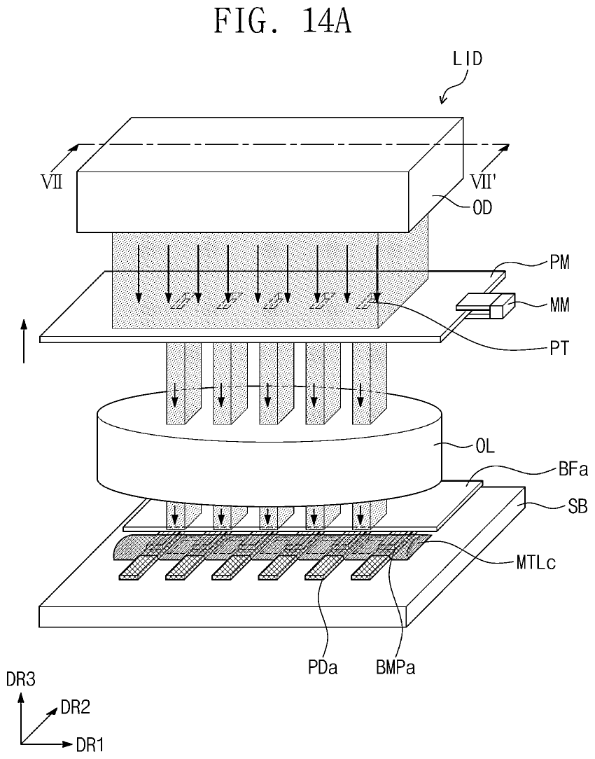

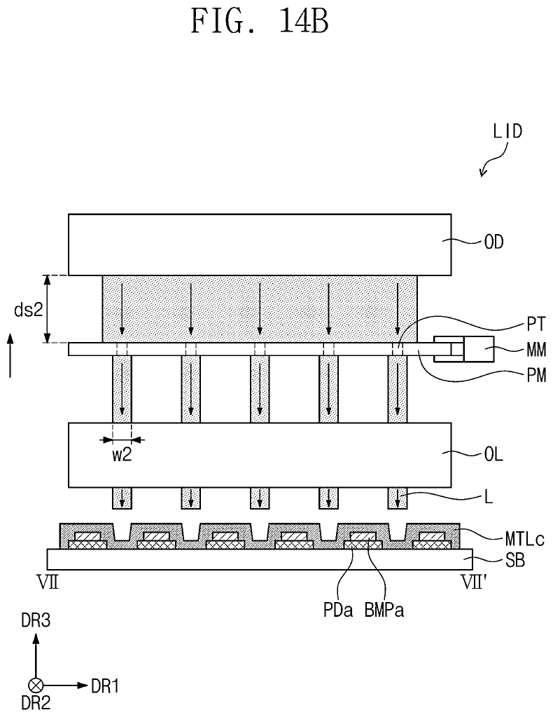

FIG. 14A is a perspective view of an embodiment of the laser irradiation device LID according to the inventive concept. FIG. 14B is a cross-sectional view of the irradiation target ISB taken along line VII-VII′ of FIG. 14A.

Referring to FIGS. 14A and 14B, the laser L patterned corresponding to the shape of the plurality of patterns PT may be emitted to a metal layer MTLc. As shown in FIG. 14B, a portion of the metal layer MTLc may be etched corresponding to a width w2 of the laser L subjected to passing through the pattern mask PM. FIGS. 14A and 14B are views showing a state in which the pattern mask PM has moved in the third direction DR3 through the moving module MM, compared to FIGS. 13A and 13B. The pattern mask PM moves in the third direction DR3 through the moving module MM, and accordingly, the width w2 of the laser L subjected to passing through the pattern mask PM may be different from the width w1 of the laser L subjected to passing through the pattern mask PM shown in FIGS. 13A and 13B. Specifically, the width w2 of the laser L subjected to passing through the pattern mask PM shown in FIG. 14B is greater than the width w1 of the laser L subjected to passing through the pattern mask PM shown in FIG. 13B. In addition, the pattern mask PM moves in the third direction DR3, and accordingly, a second distance ds2 between the optical system OD and the pattern mask PM is greater than the first distance ds1 between the optical system OD and the pattern mask PM shown in FIG. 13B.

The width w2 of the laser L subjected to passing through the pattern mask PM shown in FIG. 14B is formed to be greater than the width w1 of the laser L subjected to passing through the pattern mask PM shown in FIG. 13B, and accordingly, etching width and depth of the metal layer MTLc may become greater. That is, the etching width and depth of the metal layer MTLc may be greater than the etching width and depth of the metal layer MTLb shown in FIG. 13B.

FIG. 15A is a perspective view of an embodiment of the laser irradiation device LID according to the inventive concept. FIG. 15B is a cross-sectional view of the irradiation target ISB taken along line VIII-VIII′ of FIG. 15A.

Referring to FIGS. 15A and 15B, a metal pattern MPa may be formed from the metal layer MTLc shown in FIGS. 14A and 14B. Specifically, the metal layer MTLc may be irradiated with the laser L patterned corresponding to the shape of the plurality of patterns PT to form the metal pattern MPa. The metal pattern MPa may correspond to the metal pattern MP shown in FIG. 7B.

As shown in FIG. 15B, the metal pattern MPa may be formed corresponding to a width w3 of the laser L subjected to passing through the pattern mask PM. FIGS. 15A and 15B are views showing a state in which the pattern mask PM has moved in the third direction DR3 through the moving module MM, compared to FIGS. 14A and 14B. The pattern mask PM moves in the third direction DR3 through the moving module MM, and accordingly, the width w3 of the laser L subjected to passing through the pattern mask PM may be different from the width w2 of the laser L subjected to passing through the pattern mask PM shown in FIGS. 14A and 14B. Specifically, the width w3 of the laser L subjected to passing through the pattern mask PM shown in FIG. 15B is greater than the width w2 of the laser L subjected to passing through the pattern mask PM shown in FIG. 14B. In addition, the pattern mask PM moves in the third direction DR3, and accordingly, a third distance ds3 between the optical system OD and the pattern mask PM is greater than the second distance ds2 between the optical system OD and the pattern mask PM shown in FIG. 14B.

Referring to FIGS. 13A to 15B, the pattern mask PM moves in the third direction DR3 through the moving module MM, and accordingly, an area in which the laser L is emitted to the metal layer MTLb may gradually increase. Lastly, the substrate SB is not damaged by the laser L emitted to the metal layer MTLb having a non-uniform thickness, and also the metal pattern MPa defining an open area M-OP may be formed.

When patterning a metal layer having a non-uniform thickness with a laser, damage to a substrate disposed below the metal layer may be caused by the laser. A laser irradiation device in an embodiment of the inventive concept may include a pattern mask including a plurality of patterns, and a moving module moving the pattern mask in a thickness direction of the substrate. When the laser is emitted, an area in which the metal layer having a non-uniform thickness is irradiated with the laser may be controlled as the pattern mask moves in the direction described above. Accordingly, a plurality of metal patterns spaced apart may be formed by patterning the metal layer without damaging the substrate disposed below the metal layer.

Although the disclosure has been described with reference to a preferred embodiment of the inventive concept, it will be understood that the inventive concept should not be limited to these preferred embodiments but various changes and modifications may be made by those skilled in the art without departing from the spirit and scope of the disclosure.

Hence, the technical scope of the disclosure is not limited to the detailed descriptions in the specification but should be determined only with reference to the claims.

What is claimed is:

1. A laser irradiation device irradiating a metal layer overlapping a plurality of pad electrodes disposed on a substrate and a plurality of bump electrodes each disposed to correspond to the plurality of pad electrodes and having a non-uniform thickness with a laser to form a plurality of metal patterns spaced apart in a first direction, the laser irradiation device comprising:
an optical system including a light source emitting the laser;
a pattern mask including a plurality of patterns on which the laser emitted from the optical system is incident and through which the laser passes; and
a moving module moving the pattern mask in a direction perpendicular to the substrate while irradiating the metal layer with the laser to control an area in which the metal layer is irradiated with the laser,
wherein the plurality of pad electrodes and the plurality of bump electrodes are electrically connected through the plurality of metal patterns.

2. The laser irradiation device of claim 1, wherein the plurality of patterns is arranged in the first direction and does not overlap the plurality of metal patterns.

3. The laser irradiation device of claim 2, wherein the plurality of patterns is formed to incline at a predetermined angle in a plan view with respect to the plurality of pad electrodes.

4. The laser irradiation device of claim 2, wherein the plurality of patterns comprises first sub-patterns and second sub-patterns, which are spaced apart in a second direction crossing the first direction.

5. The laser irradiation device of claim 4, wherein the first sub-patterns and the second sub-patterns are alternately disposed in the first direction in a plan view.

6. The laser irradiation device of claim 1, wherein a plurality of open areas is defined between two adjacent metal patterns among the plurality of metal patterns.

7. The laser irradiation device of claim 6, wherein the plurality of patterns overlaps the plurality of open areas in a plan view.

8. The laser irradiation device of claim 1, wherein the pattern mask is disposed between the optical system and the substrate.

9. The laser irradiation device of claim 8, wherein the pattern mask is disposed parallel to the substrate.

10. The laser irradiation device of claim 1, wherein the laser emitted from the light source has a wavelength of about 200 nanometers to about 400 nanometers.

11. The laser irradiation device of claim 1, wherein the laser emitted from the optical system comprises a laser line beam.

12. The laser irradiation device of claim 1, further comprising an optical lens between the substrate and the pattern mask.

13. The laser irradiation device of claim 12, wherein the optical lens comprises a chromatic aberration lens.

14. A method for manufacturing a display device, the method comprising:
providing a plurality of pad electrodes disposed on a base layer and arranged in a first direction, and a plurality of bump electrodes disposed on the plurality of pad electrodes and overlapping each of the plurality of pad electrodes in a plan view;
disposing a metal layer having a non-uniform thickness on the plurality of pad electrodes and the plurality of bump electrodes;
irradiating the metal layer with a laser, using a laser irradiation device including a pattern mask including a plurality of patterns; and
forming a plurality of metal patterns overlapping the plurality of pad electrodes and the plurality of bump electrodes and spaced apart in the first direction,
wherein the plurality of pad electrodes and the plurality of bump electrodes are electrically connected through the plurality of metal patterns.

15. The method of claim 14, wherein the irradiating the metal layer with the laser comprises patterning the metal layer, in the plan view, overlapping an area between two adjacent pad electrodes among the plurality of pad electrodes.

16. The method of claim 15, wherein the patterning the metal layer comprises irradiating the metal layer, in the plan view, overlapping an area between the two adjacent pad electrodes among the plurality of pad electrodes with the patterned laser subjected to passing through the pattern mask.

17. The method of claim 16, wherein the patterning the metal layer comprises moving the pattern mask in a direction away from the base layer through a moving module.

18. The method of claim 17, wherein while the pattern mask moves, an irradiation area of the laser patterned by passing through the pattern mask gradually increases, and a thickness of the metal layer gradually decreases.

19. The method of claim 16, wherein a plurality of open areas is defined between two adjacent metal patterns among the plurality of metal patterns, and
the plurality of open areas overlaps the plurality of patterns in the plan view.

20. The method of claim 14, further comprising planarizing the metal layer, using the laser irradiation device including a planarization mask before the forming the plurality of metal patterns.
